(19) United States
(12) Patent Application Publication
(10) Pub. No.: US 2007/0077769 A1
(43) Pub. Date: Apr. 5, 2007

(54) Method of removing organic contaminants from a semiconductor surface

(75) Inventors: Stefan DeGendt, Wijnegem (BE); Peter Snee, Navan (IE); Marc Heyns, Linden (BE)

Correspondence Address: MCDONNELL BOEHNEN HULBERT & BERGHOFF LLP, 300 S. WACKER DRIVE, 32ND FLOOR, CHICAGO, IL, 60606, US

(73) Assignee: Interuniversitair Micro-Elektronica Centrum vzw, Leuven (BE)

(21) Appl. No.: 11/413,625

(22) Filed: Apr. 28, 2006

Related U.S. Application Data
(63) Continuation of application No. 09/022,834, filed on Feb. 13, 1998, now abandoned.
(60) Provisional application No. 60/040,309, filed on Feb. 14, 1997.
(60) Provisional application No. 60/042,389, filed on Mar. 25, 1997.
(60) Provisional application No. 60/066,261, filed on Nov. 20, 1997.

(30) Foreign Application Priority Data
Feb. 10, 1998 (EP) 988700266

(51) Int. Cl. C23G 1/00; C03C 25/68; H01L 21/461; H01L 21/302

(52) U.S. Cl. 438/725; 216/58; 438/745; 134/2; 438/715

(57) ABSTRACT

A method for removing organic contaminants from a semiconductor surface whereby the semiconductor is held in a tank and the tank is filled with a fluid such as a liquid or a gas. Organic contaminants, such as photoresist, photoresidue, and dry etched residue, occur in process steps of semiconductor fabrication and at times, require removal. The organic contaminants are removed from the semiconductor surface by holding the semiconductor inside a tank. The method may be practiced using gas phase processing or liquid phase processing. The tank is filled with a gas mixture, a liquid, and/or a fluid, such as water, water vapor, ozone and/or an additive acting as a scavenger (a substance which counteracts the unwanted effects of other constituents of the system).

### REFERENCE TO RELATED APPLICATIONS

This application claims priority benefits under 35 U.S.C. §119(e) to U.S. provisional application Ser. No. 60/040,309, filed on Feb. 14, 1997, to U.S. provisional application Ser. No. 60/042,389, filed on Mar. 25, 1997, and to U.S. provisional application Ser. No. 60/066,261, filed on Nov. 20, 1997.

### BACKGROUND OF THE INVENTION

A. Field of the Invention

The present invention is related to a method for removing organic contaminants from a semiconductor surface.

The present invention is also related to the use of this method for specific applications such as VIA etching.

B. Description of Related Art

The semiconductor surface preparation prior to various processing steps such as oxidation, deposition or growth processes, has become one of the most critical issues in semiconductor technology. With the rapid approach of sub halfmicron design rules, very small particles and low levels of contamination or material impurities (˜10¹⁰ atoms/cm² and lower) can have a drastic effect on process yields. The contaminants that are to be removed from a semiconductor surface include metallic impurities, particles and organic material. A commonly used technique to reduce foreign particulate matter contamination level on semiconductor surfaces, is the immersion of wafers in chemical solutions.

Organic material is one of the contaminants that has to be removed from the semiconductor wafer surface. In a pre-clean stage, absorbed organic molecules prevent cleaning chemicals from contacting with the wafer surface, thus leading to non-uniform etching and cleaning on the wafer surface. In order to realize contamination free wafer surfaces, organic impurities have to be removed before other wafer cleaning processes. Traditional wet cleaning processes involve the use of sulfuric peroxide mixtures (SPM) to remove organic molecules. However, SPM uses expensive chemicals and requires high processing temperatures, and causes problems in terms of chemical waste treatment.

Other sources of organic contamination also arise during a standard IC process flow. Such sources can be photoresist layers or fluorocarbon polymer residues that are deposited on a substrate.

The fluorocarbon residues originate from the exposure of semiconductor (silicon) substrates to dry oxide etch chemistries. In conventional oxide etching with fluorocarbon gases, an amount of polymer is intentionally generated in order to achieve a vertical sidewall profile and better etch selectivity to the photoresist mask and underlying film. Etch selectivity in a SiO₂—Si system can be achieved under certain process conditions through the formation of fluorocarbon based polymers. The polymerisation reaction occurs preferably on Si, thus forming a protective coating and etch selectivity between Si and SiO₂. After selective etching, both resist and polymer-like residue must be removed from the surface. If the polymer is not completely removed prior to the subsequent metal deposition, the polymer will mix with sputtered metal atoms to form a high resistance material resulting in reliability concerns. Methods of polymer removal depend on the plasma etch chemistry, plasma source and the composition of the film stack. However, for dry processes, the application of O2 or H2 containing gases have been applied to remove the fluorocarbon polymers. For wet cleaning techniques an amine based solvent (U.S. Pat. No. 5,279,771 and U.S. Pat. No. 5,308,745, which are hereby incorporated by reference) is frequently applied. Organic photoresist removal generally involves wet or dry oxidative chemistries (i.e. O2 plasma, SPM) or dissolution processes based on solvent strippers. These processes are both expensive and environmentally harmful in terms of waste treatment.

In an attempt to find alternative efficient cleans for the removal of organic contamination (including photoresist and etch residues) from Si surfaces, the use of ozonated chemistries has been investigated. Ozone has been used extensively in the field of waste water treatment and drinking water sterilisation, because of its strong oxidising power. An additional benefit of ozone is its harmless residue after decomposition and/or reaction (H₂O, CO₂, O₂). It is generally presumed that oxidative action of ozone towards organic contamination involves two different oxidation pathways, either direct oxidation or advanced oxidation. Direct oxidation or ozonolysis involves molecular ozone as the prime oxidant. It predominantly occurs at carbon-carbon double bonds. This type of oxidation is favored in the low pH region of the waste water. Advanced oxidation involves secondary oxidants as the prime oxidant (e.g. OH radicals). This type of oxidation is more reactive, but less sensitive and is predominant at conditions that favor OH radical formation, such as high pH, elevated temperature, addition of enhancers (e.g. H₂O₂), UV radiation. In real life situations, one often deals with a mixture of contaminants having a different reactivity towards ozone. However, both oxidation pathways are concurrent and conditions that favor advanced oxidation pathways will occur at the expense of the efficiency of eliminating organic contamination with higher reactivity towards molecular ozone. In order to optimize the organic removal efficiency of ozonated chemistries, it is critical to identify the parameters that influence both oxidation pathways.

In recent years, ozone was introduced in the microelectronics industry because of its strong oxidizing capabilities. When ozone gas is dissolved into water, its self-decomposition time gets shorter compared to the gaseous phase. During self-decomposition, ozone generates OH radicals as a reaction by-product, which is according to G. Alder and R. Hill in J. Am. Chem. Soc. 1950, 72 (1984), hereby incorporated by reference, believed to be the reason for decomposition of organic material.

U.S. Pat. No. 5,464,480, which is hereby incorporated by reference, describes a process for removing organic material from semi-conductor wafers. The wafers are contacted with a solution of ozone and water at a temperature between 1° and 15° C. Wafers are placed into a tank containing deionized water, while diffusing ozone into the (sub-ambient) deionized water for a time sufficient to oxidize the organic material from the wafer, while maintaining the deionized water at a temperature of about 1° to about 15° C., and thereafter rinsing the wafers with deionized water. The purpose of lowering the temperature of the solution to a range between 1° and 15° C. is to enable sufficiently high ozone concentrations into water to oxidize all of the organic material onto the wafer into insoluble gases.

European Patent Application EP-A-0508596 describes a spray-tool process, whereby during the cleaning process, various liquid chemicals, ultra-pure water or a mixed phase fluid comprising an ozone-containing gas and ultra pure water are sprayed onto substrates or semiconductor wafers in a treating chamber filled with ozone gas. Rotation is necessary to constantly renew thin films of treating solution and promoting removal of undesired materials by means of centrifugal force.

U.S. Pat. No. 5,181,985, which is hereby incorporated by reference, describes a process for the wet-chemical surface treatment of semiconductor wafers in which aqueous phases containing one or more chemically active substances in solution act on the wafer surface, consisting of spraying a water mist over the wafer surface and then introducing chemically active substance in the gaseous state so that these gaseous substances are combined with the water mist in order to have an interaction of the gas phase and the liquid phase taking place on the surface of the semiconductor wafers. The chemical active substance are selected from the group consisting of gases of ammonia, hydrogen chloride, hydrogen fluoride, ozone, ozonized oxygen, chlorine and bromine. The water is introduced into the system at a temperature of 10° C. to 90° C.

U.S. Pat. No. 5,503,708, which is hereby incorporated by reference, describes a method and an apparatus for removing an organic film wherein a mixed gas including an alcohol and one of ozone gas and an ozone-containing gas is supplied into the processing chamber at least for a period before that the semiconductor wafer is placed in said processing chamber, so that the mixed gas will act on the organic film formed on the surface of the semiconductor wafer.

Document JP-A-61004232 is describing a cleaning method of semiconductor substrates. The method is presented as an alternative for traditional acid-hydrogen peroxide cleans, which in the prior art are used for heavy metal reduction on silicon wafers. Substrates are dipped in a solution of an undiluted organic acid, e.g. formic acid or acetic acid filled into a cleaning tank wherein ozone or oxygen is supplied from the bottom of the tank so as to bubble into the solution, said solution being heated to a temperature comprised between 100° C. to 150° C. Organic waste matter is oxidized by means of the ozone and can be dissolved and removed. In other words, this Japanese publication describes cleaning of heavy metals on semiconductor wafers through formation of metal formate or metal acetate compounds and of dissolving the organic waste matter from semiconductor wafers by means of ozone.

### AIMS OF THE PRESENT INVENTION

The present invention aims to suggest an improved method for the removal of organic contaminants from a semiconductor substrate.

More particularly, the present invention aims to suggest a method of removal of organic contamination such as photoresist, photoresidue, dry etched residue which can occur in any process step of the fabrication of semiconductor substrate.

### SUMMARY OF THE PRESENT INVENTION

As a first aspect, the present invention is related to a method of removing organic contaminants from a substrate comprising the steps of holding said substrate in a tank, filling said tank with a gas mixture comprising water vapor, ozone and an additive acting as a scavenger.

As a second aspect, the present invention is related to a method for removing organic contaminants from a substrate, comprising the steps of:

holding said substrate in a tank;

filling said tank with a liquid comprising water, ozone and an additive acting as a scavenger; and

maintaining said liquid at a temperature less than the boiling point of said liquid.

As a third aspect, the present invention is related to a method for removing organic contaminants from a substrate comprising the steps of:

holding said substrate in tank;

filling said tank with a fluid comprising water, ozone and an additive acting as a scavenger, and wherein the proportion of said additive in said fluid is less than 1% molar weight of said fluid.

By scavenger, it is meant a substance added to a mixture or any other systems such as liquid, gas, solution in order to counteract the unwanted effects of other constituents of the mixture or system.

Said additive should preferably act as OH radical scavengers. A radical is an uncharged species (i.e. an atom or a di-atomic or poly-atomic molecule) which possesses at least one unpaired electron. Examples of scavengers can be carboxylic or phosphonic acid or salts thereof such as acetic acid (CH₃COOH), and acetate (CH3COO⁻) as well as carbonate (HₓCO₃^{-(2-x)}) phosphate (HₓPO4^{-(3-x)}).

The invention can be used in the fabrication of silicon wafers for Integrated Circuits. The invention can also be used in related fields, like the fabrication of flat panel displays, solar cells, or in micro-machining applications or in other fields wherein organic contaminants have to be removed from substrates.

### BRIEF DESCRIPTION OF THE DRAWINGS

FIG. 1 is a schematic representation of a deep VIA etch structure.

FIG. 2 is a schematic representation of an Al overetched VIA structure.

FIG. 3 is a representation of the experimental set-up used in the gas phase processing.

FIG. 4 is representing an SEM micrograph of a VIA structure prior to any cleaning treatment.

FIG. 5 represents an SEM micrograph of a VIA structure after 45 minutes O2 dry strip.

FIG. 6 represents an SEM micrograph of a deep VIA as represented in FIG. 1 after 10 minutes exposure to a preferred embodiment of the method of the present invention.

FIG. 7 represents an SEM micrograph of Al overetched via according to FIG. 2 after 10 minutes exposure to a preferred embodiment of the method of the present invention.

FIG. 8 is representing the experimental set-up of the liquid phase processing.

FIG. 9 represents the resist removal process efficiency number for positive and negative resist removal as a function of the acetic acid concentration.

FIGS. 10 & 11 represent the main parameter effects on resist removal rate and resist removal process efficiency number for positive resist removal.

FIG. 12 represents the resist removal efficiency as a function of the temperature and the ozone concentration in a static system.

FIG. 13 represents the resist removal efficiency as a function of the temperature and ozone concentration in bubble or moist gasphase processing.

FIG. 14 represents a possible scheme of reactions in an aqueous ozone.

FIG. 15 represents the effect of OH radical scavenging on ozone concentration in an overflow tank.

FIG. 16 represents the effect of repeated addition of hydrogen peroxide to a de-ionised water solution spiked with acetic acid.

### DETAILED DESCRIPTION OF SEVERAL EMBODIMENTS OF THE PRESENT INVENTION

The purpose of the present invention is related to a method for removing organic contamination from a substrate. Said substrate can be a semiconductor surface.

Said method can be applied for the removal of photoresist and organic post-etch residues from silicon surfaces. Said organic contamination can be a confined layer covering at least part of said substrate. Said confined layer can have a thickness in a range of submonolayer coverage to 1 μm. Said method is applicable for either gasphase or liquid processes.

In the following specification, a first preferred embodiment of the invention for gas phase processing and a second preferred embodiment for liquid phase processing are described.

Description of a First Preferred Embodiment for Gasphase Processing

In said gasphase process, said substrates are placed in a tank such that said substrates are in contact with a gas mixture containing water vapor, ozone and an additive acting as a scavenger.

Said scavenger is a substance added to said mixture to counteract the unwanted effects of other constituents. Said scavenger typically acts as an OH radical scavenger. Said additive can be a carboxylic or a phosphonic acid or salts thereof. More preferably, said additive is acetic acid.

The proportion of said additive in said gas mixture is preferably less than 10% molar weight of said gas mixture. The proportion of said additive in said gas mixture is more preferably less than 1% molar weight of said gas mixture. Even more preferably, the proportion of said additive in said gas mixture is less than 0.5% molar weight of said gas mixture. Even more preferably, the proportion of said additive in said gas mixture is less than 0.1% molar weight of said gas mixture.

Said gas mixture can also contain oxygen, nitrogen, argon or any other inert gas. The ozone concentration of said gas mixture is typically below 10% molar weight. The water vapor is typically saturated at the operational temperature of said mixture. The operational temperature of said mixture is below 150° C. and preferably higher than the temperature of said substrate.

Said method also comprises a step of rinsing said substrate with a solution. Said rinsing solution comprises preferably de-ionized water. Said rinsing solution can further comprise HCl and/or HF and/or HNO3 and/or CO2 and/or O3. Said rinsing solution can also be subjected to megasone agitation.

According to a preferred embodiment, the method can also comprise the step of filling said tank with a liquid comprising essentially water and said additive, the liquid level in said tank remaining below the substrate and wherein said liquid is heated. Said tank is then filled with a saturated water vapor containing said additive. Said tank is further filled with ozone. According to a preferred embodiment, the ozone can be bubbled through said liquid. Preferably, said liquid is heated in a range between 16° C. and 99° C. and even more preferably between 20° C. and 90° C. Even more preferably, the liquid is heated between 60° C. and 80° C.

According to the best mode of the embodiment, the set-up denoted as moist ozone gasphase process uses a quartz container filled with only a minute amount of liquid, sufficient to fully immerse an O₃ diffuser. The liquid is DI water, spiked with an additive, such as acetic acid. A lid is put on the quartz container. The liquid is heated to 80° C. Wafers are placed directly above the liquid interface but are not immersed. The ozone diffusor is fabricated from fused silica, and the ozone generator (Sorbius) is operated with an oxygen flow which maximizes the ozone content in the gas flow. In the best mode embodiment, a flow of 3 l/min O₂ is used. At all time the ozone is bubbled directly into the liquid (no bubble reduction) throughout the experiment. Heating of the liquid in a sealed container and continuous O₃ bubbling through the liquid exposes the wafers to a moist O₃ ambient. In the gasphase experiment, operational temperature was 80° C., while the DI water is acidified (1/100 volume ratio) with acetic acid. Wafers are to be processed sufficiently long and a rinse step follows the moist gas phase treatment. In an embodiment, wafers are processed for 10 minutes, and subsequently rinsed in DI water for 10 minutes.

Description of a Second Preferred Embodiment for Liquid Processing

In said liquid process, said substrates are placed in a tank such that said substrates are in contact with a liquid mixture comprising water, ozone and an additive acting as a scavenger. Said scavenger is a substance added to said mixture to counteract the unwanted effects of other constituents. Said scavenger typically acts as an OH radical scavenger.

Said additive can be a carboxylic or a phosphonic acid or salts thereof, preferably said additive is acetic acid. The proportion of said additive in said liquid is less than 1% molar weight of said liquid. Preferably, the proportion of said additive in said liquid is less than 0.5 molar weight of said liquid. More preferably, the proportion of said additive in said liquid is less than 0.1% molar weight of said liquid. Said liquid can also be subjected to megasone agitation.

According to a preferred embodiment, the method also comprises a step of maintaining said liquid at a temperature less than the boiling point of said liquid. Preferably, the temperature of said liquid is lower than 100° C. More preferably, the temperature of said liquid is comprised between 16° C. and 99° C. More preferably, the temperature of said liquid is comprised between 20° C. and 90° C. Even more preferably, the temperature of said liquid is comprised between 60° C. and 80° C.

Preferably, the ozone is bubbled through said liquid which allows a contact of the bubbles of ozone with the substrates.

According to a preferred embodiment, said method also comprises a step of rinsing said substrate with a rinsing solution. Preferably, said rinsing solution comprises de-ionized water. More preferably, said rinsing solution further comprises HCl and/or HF and/or HNO₃ and/or CO₂ and/or O₃. Said rinsing solution can also be subjected to megasone agitation.

According to the best mode of the embodiment of the invention, the following set-up is used: The O₃ set-up (immersion based), denoted as bubble experiment, consists of a quartz container holding 7 litres of a liquid and an ozone diffuser located at the bottom of the tank. The liquid can be heated. Operational temperature is 45° C. The ozone diffusor is fabricated from fused silica, and the ozone generator (Sorbius) is operated with an oxygen flow which maximizes the ozone content in the gas flow. In the best mode embodiment, a flow of 3 l/min O₂ is used. At all time the ozone is bubbled directly into the quartz tank (no bubble reduction) throughout the experiment. The substrates are positioned directly above the ozone diffuser, and immersed in the liquid. As such O₂/O₃ bubbles contact the surface. The substrates are exposed to an ozone treatment with varying acetic acid concentrations in the bubble set-up. The substrates are exposed to an ozone clean between 0-11,5 mol/l (0, 0.1 ml (0.46 mmol/l), 1.0 ml (2.3 mmol/l) and 5.0 ml (11.5 mmol/l)) of acetic acid added to the 7 liter of DI water.

The present invention is also related to specific applications of the method as described in the two preferred embodiments of the present invention.

Application 1: Via Cleaning

The method of the present invention can be applied for wafer cleaning technologies after plasma etching processes especially into submicron processes. Dry etching of silicon and its compounds is based on the reaction with fluorine, with resulting fluorocarbon polymer contamination. The fluorocarbon residues originate from the exposure of semiconductor (silicon) substrates to dry oxide etch chemistries. In conventional oxide etching with fluorocarbon gases, an amount of polymer is intentionally generated in order to achieve a vertical sidewall profile and better etch selectivity to the photoresist mask and underlying film. Etch selectivity in a SiO₂−Si system can be achieved under certain process conditions through the formation of fluorocarbon based polymers.

The polymerisation reaction occurs preferably on Si, thus forming a protective coating and etch selectivity between Si and SiO₂. After selective etching, both resist and polymer-like residue must be removed from the surface. If the polymer is not completely removed prior to the subsequent metal deposition, the polymer will mix with sputtered metal atoms to form a high resistance material resulting in reliability concerns. Methods of polymer removal depend on the plasma etch chemistry, plasma source and the composition of the film stack. However, for dry processes, O₂ or H₂ containing gases have been applied to remove the fluorocarbon polymers. For wet cleaning techniques an amine based solvent U.S. Pat. No. 5,279,771 and U.S. Pat. No. 5,308,745 is frequently applied. These processes are frequently both expensive and environmentally harmful in terms of waste treatment.

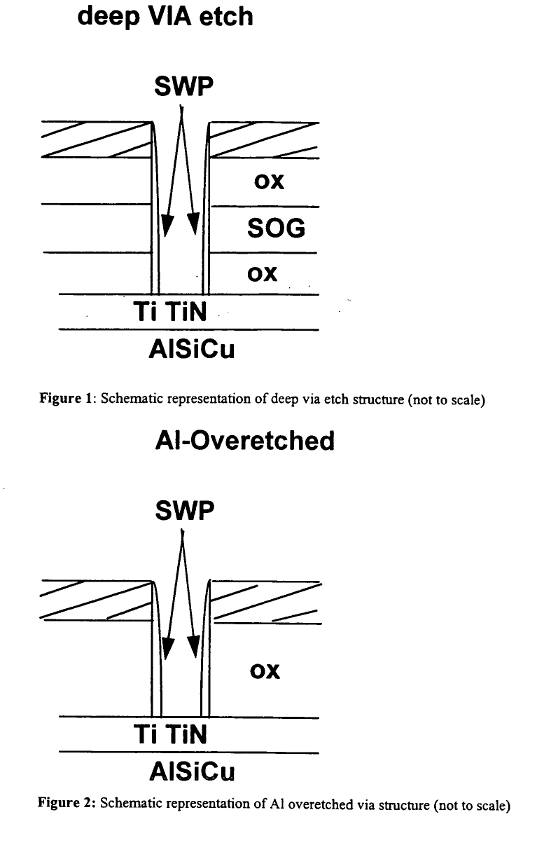

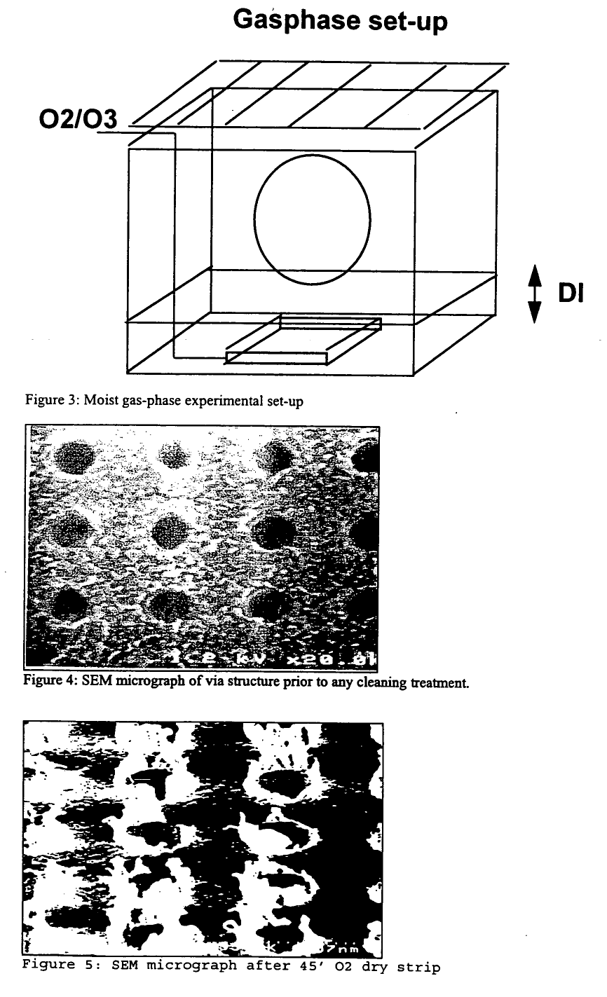

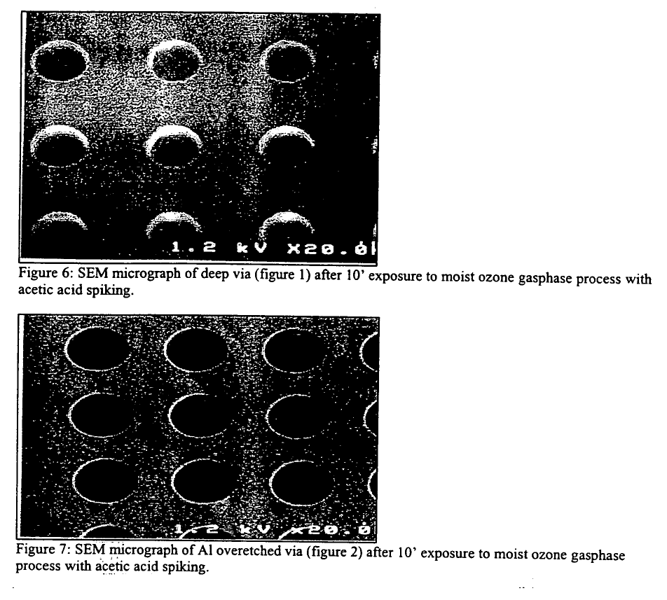

FIGS. 1 and 2 shows different VIA test structures prepared on p-type wafers. The first structure consists of 500 nm oxide, 30/80 nm Ti/TiN, 700 nm AlSiCu, 20/60 nm Ti/TiN, 250 nm oxide, 400 nm SOG and 500 nm oxide (starting from the silicon substrate). The second structure contains the following layers; 500 nm oxide, 30/80 nm Ti/TiN, 700 nm AlSiCu, 20/60 nm Ti/TiN and 500 nm oxide (also starting from the silicon substrate). Subsequently, these structures are coated with I-line resist and exposed through a mask set with contact holes ranging from 0.4 μm till 0.8 μm in diameter. VIA's were etched in a CF4/CHF3 plasma. For the first set of wafers VIA's are etched through the 500 nm oxide/400 nm SOG/250 nm oxide, stopping on TiTiN/Al, for the second set of wafers, VIA's are overetched through the 500 nm oxide layer into the TiTiN/Al layers. Wafers are exposed to the ozone clean directly (i.e. with resist layer and sidewall polymers on the wafer).

The set-up used for this application is represented in FIG. 3. The set-up denoted as moist ozone gasphase process uses a quartz container filled with only a minute amount of liquid, sufficient to fully immerse an O₃ diffuser. The liquid is DI water, spiked with an additive, such as acetic acid. A lid is put on the quartz container. The liquid is heated to 80° C. Wafers are placed directly above the liquid interface but are not immersed. The ozone diffusor is fabricated from fused silica, and the Sorbius generator is operated with a flow of 3 l/min O₂ flow. At all time the ozone is bubbled directly into the quartz tank (no bubble reduction) throughout the experiment. Heating of the liquid in a sealed container and continuous O₃ bubbling through the liquid exposes the wafers to a moist O₃ ambient. In the gasphase experiment, operational temperature was 80° C., while the DI water is acidified (1/100 volume ratio) with acetic acid. In all cases, wafers are processed for 10 minutes, and subsequently rinsed in DI water for 10 minutes.

Quarter wafers are used, as such, the exact same wafer is used for all treatments; facilitating relative comparison of the cleaning efficiencies of either process. Cleaning efficiency is evaluated from SEM measurements (on 0.6 μm VIA's). For reference, wafers were also dry stripped for 45 minutes during an O2 plasma treatment (i.e. leaving sidewall polymers on the wafer).

FIG. 4 shows SEM micrograph of VIA structures (FIG. 1) prior to exposure to any cleaning treatment, i.e. with resist and side-wall polymers present. FIG. 5 is a SEM micrograph of VIA structure in FIG. 1 after 45 minutes O2 dry strip. SEM micrographs for both structures in FIGS. 1 and 2, after 10 minutes exposure to the optimized moist ozone gasphase process with acetic acid addition, are shown in FIGS. 6 and 7 respectively.

It can be seen immediately that after 45 minutes O2 dry strip treatment, side wall polymers are still clearly visible. However, if we consider the gasphase experiment, we do observe an excellent cleaning efficiency (FIGS. 6 and 7). Note that identical wafers and process times were used for all ozone experiments, making the effect even more significant. In the gasphase experiment, resist coating as well as sidewall post-etch polymer residues are no longer observed on the surface.

Moist ozone gasphase treatment with acetic acid spiking has been demonstrated to be efficient in removing both resist layers and sidewall polymer residues from VIA-etched wafers. This is due to both physical and chemical enhancement of the ozone efficiency for removal of organic contamination.

Application 2: Resist Removal

As claimed hereabove, chemical additives such as acetic acid can have impact on the removal efficiency of organic contamination by means of ozonated chemistries. For this purpose, wafers coated with a resist layer are exposed to various ozonated DI water mixtures. The resist removal efficiency is evaluated. Wafers are coated with positive (IX500el from JSR electronics) and negative (UVNF from Shipley) resist. The resist covered wafers are given a DUV bake treatment to harden the resist prior to use. Also implanted wafers (5e13 at/cm2 P) with positive resist are processed. Resist thickness is monitored ellipsometrically before and after the process.

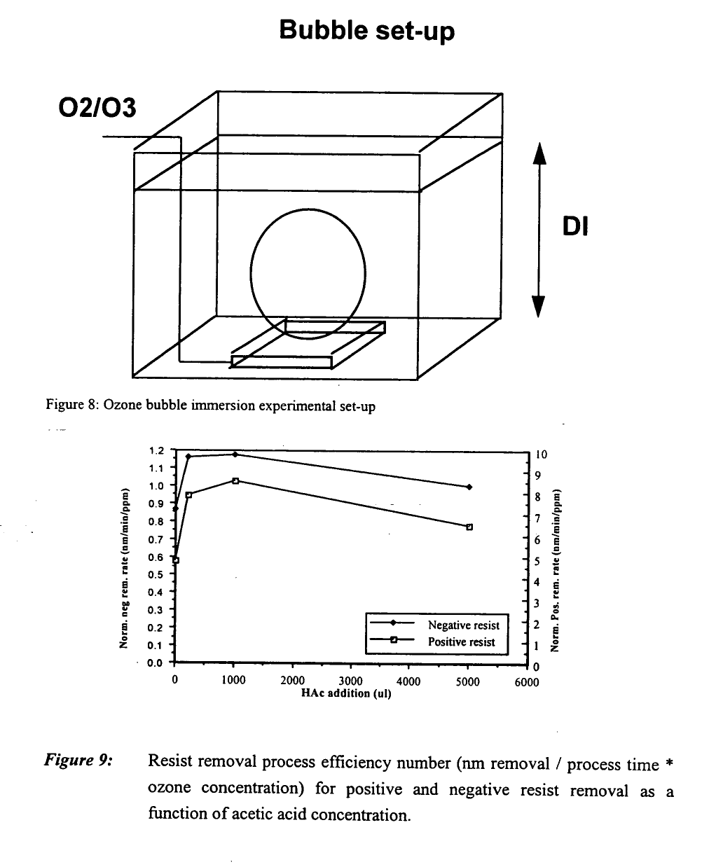

The O₃ reference set-up (immersion based) used for another specific application denoted as bubble experiment is represented in FIG. 8, consists of a quartz container holding 7 litres of a liquid and an ozone diffuser located at the bottom of the tank. The liquid can be heated. Operational temperature is 45° C. The ozone diffusor is fabricated from fused silica, and the Sorbius generator is operated with a flow of 3 l/min O₂ flow. At all time the ozone is bubbled directly into the quartz tank (no bubble reduction) throughout the experiment. Wafers are positioned directly above the ozone diffuser, and immersed in the liquid. As such O₂/O₃ bubbles contact the surface, the wafers are exposed to an ozone treatment with varying acetic acid concentrations in the bubble set-up shown in FIG. 7. The unimplanted resist wafers are exposed to an ozone clean with 0, 0.1 ml (0.46 mmol/l), 1.0 ml (2.3 mmol/l) and 5.0 ml (11.5 mmol/l) of acetic acid added to the 7 liter of DI water. The implanted wafers are exposed to cleans with either 0 or 11.5 mmol/l of acetic acid added.

For implanted resist, removal efficiency is increased by about 50% (60 nm/min versus 90 nm/min) upon addition of the indicated quantity of acetic acid. Results for unimplanted resist are presented in FIG. 9. A process efficiency number is defined, i.e. the resist removal efficiency normalized versus ozone concentration, and expressed as a removal rate per unit of process time. The as such defined process efficiency number increases from 0.8 till 1.2 nm/(min*ppm) for negative resist and from 4.5 till 8.5 nm/(min*ppm) for positive resist. Despite the order of magnitude difference for positive and negative resist removal, general trends are identical. It can be seen that a positive effect on the process efficiency number is generated from acetic acid addition.

Application 3: Resist Removal

Based on the above, experimentally designed trials are done. Effect under study is the resist removal efficiency by means of ozonated chemistries, with the use of chemical additives. Both positive and negative postbaked resist are studied. The O₃ reference set-up (immersion based), denoted as bubble experiment and presented in FIG. 8 is used. In order to have a better assessment of the effect of the individual variables under evaluation, wafers were not exposed directly to the ozone bubbles. This lower ozone availability (no bubble or gas contact) is reflected in the lower removal rate and process efficiency number compared to application 2. Variables under consideration are acetic acid, hydrogenperoxide and ozone (by varying the oxygen flow) concentration, as well as temperature and pH of the solution. The effect of pH (varied between 2 and 5, HNO3 addition) is included to determine whether or not the impact of acetic acid is not induced by the changing pH. Hydrogenperoxide is added as it is a known OH radical generator. Quantities added are 0, 0.1 or 0.2 ml (Ashland, GB, 30%). Acetic acid (Baker, reagent grade, 99%) addition is either 0, 0.5 or 1 ml in 7 liter of DI water. Temperature was varied between 21 and 40° C., while O₃ concentration was controlled from the O₂ flow through the generator. Low flow is 3 l/min, high flow is 5 l/min. Both for positive and negative resist removal, results are expressed as resist removal rate per unit of time. Experimental results are presented in Table I. RS/Discover is used to analyse the experimental results. This is done using a stepwise multiple regression according to a least squares method and a quadratic model. This model accounts for about 90% of the variation observed in the experimental results.

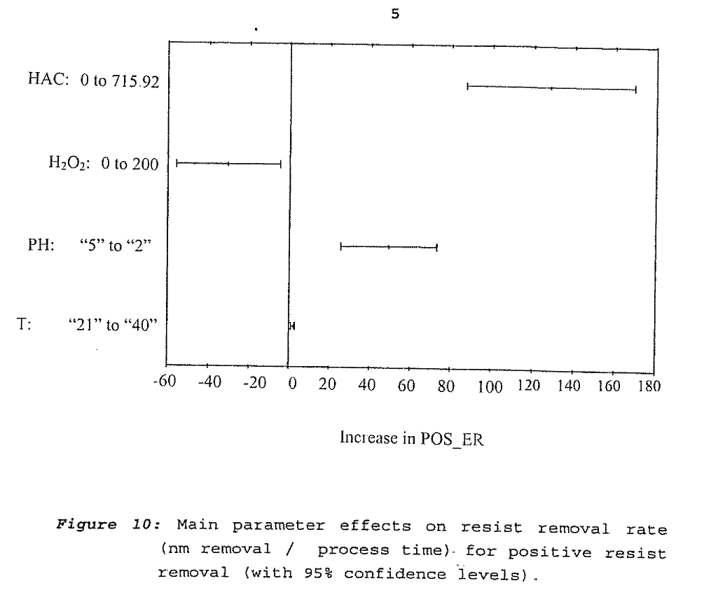

Only results for positive resist are presented in FIGS. 10 and 11, the statistics for negative resist removal are identical. The main effects on all of the responses is shown in FIG. 10. Notice that the largest positive effect on resist removal is due to the change in acetic acid concentration (going from 0 till 715 μl HAc addition), with pH being of far less importance. Also, the resist removal rate is reduced by the addition of hydrogenperoxide (going from 0 till 200 μl). From this graph it could be concluded that the temperature is of little importance. However, the ozone concentration is strongly dependent on the temperature (solubility and stability relate inversely with temperature), which biases the results. Therefore, a process efficiency number is defined; i.e. the resist removal efficiency normalized versus ozone concentration and expressed as a removal rate per unit of time and per unit of ozone (i.e. nm/(min*ppm)). The as such obtained process efficiency number varies between 0.2 and 4 nm/(min*ppm) for positive resist and 0.03 and 0.4 nm/(min*ppm) for negative resist. The outcome of the impact of the various parameters on the process efficiency number is plotted in FIG. 11 for positive resist removal. Despite the order of magnitude difference between positive and negative resist removal, general trends are identical. It can be seen that a positive effect on the process efficiency number is generated from acetic acid addition, ozone concentration and temperature enhancement.

Application 4: Resist Removal

In a further study of the method of the present invention, another experiment is described hereunder, wherein no acetic acid is added to the solution.

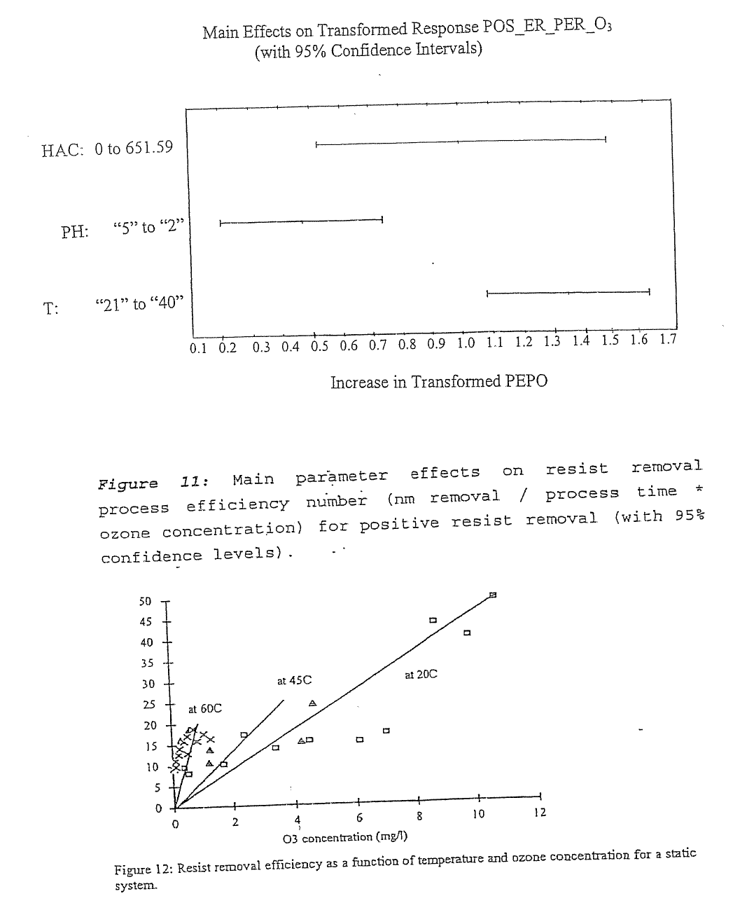

The main requirement for the ozonated chemistries is fast and complete removal of organic contaminants (e.g. clean room air components, photoresist or side-wall polymers). Critical parameters influencing the removal efficiency are to be identified. It was assessed above that acetic acid spiking influenced results, however also other parameters such as ozone concentration and temperature are likely important. Therefore, the impact of O₃ concentration and operational temperature for positive resist removal efficiency was evaluated experimentally. Wafers coated with a 5 nm thick photoresist coating were prepared and immersed in a static bath containing DI water (set-up as in FIG. 8, but ozone bubbling off during immersion). Ozone concentration was varied between 0 and 12 ppm, and temperature between 20, 45 and 70° C. Purposely, 1 min cleans are done in static conditions (i.e. gas flow off, after O₃ saturation of DI), to assess the parameter impact. Principal results are shown in FIG. 12, where cleaning efficiency is plotted versus O₃ concentration for the three different temperature ranges. Removal is only 50% due to the small processing time and static conditions (limited ozone availability). It can be seen that cleaning efficiency per unit of ozone, is more performing at elevated temperatures, while total removal in the time frame studied is more performing at higher ozone concentration. However, O₃ solubility decreases with temperature, while process performance increases with temperature.

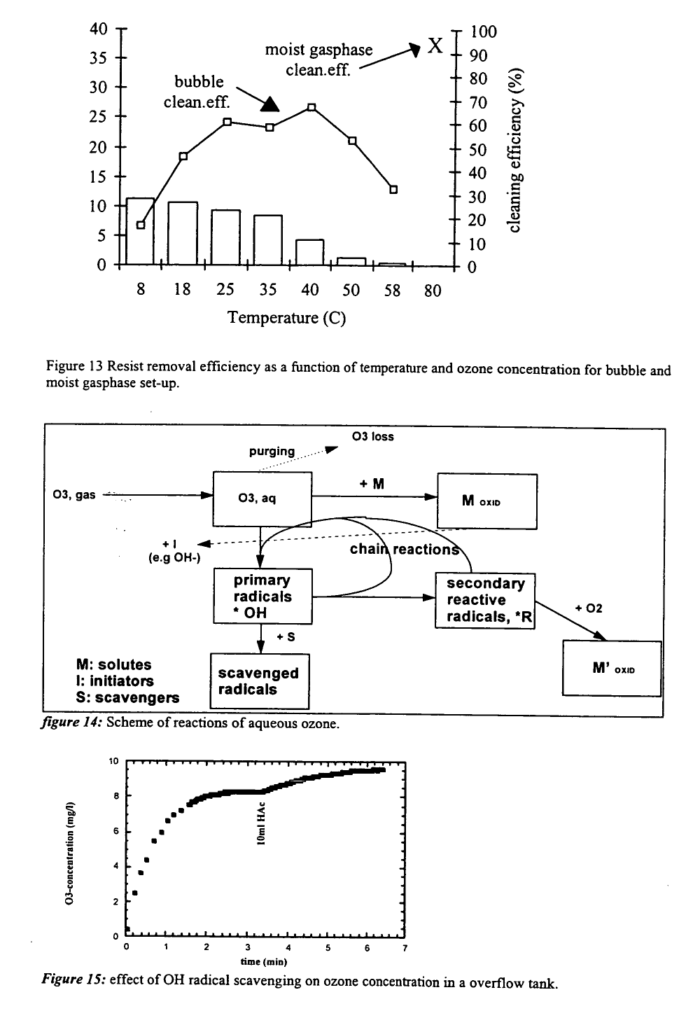

Ozone concentration in solution, and thus oxidizing capabilities and cleaning performance can be maximized relying on physical aspects. One process, described previously in U.S. Pat. No. 5,464,480 operates the water at reduced temperature (chilled), in order to increase ozone solubility. Disadvantages are the lowered reactivity and longer process times due to reaction kinetics. Another possibility to improve the ozone concentration is using more efficient ozone generators and/or ozone diffusor systems to transfer ozone into the DI water. From the above observations however, it is believed that any optimized process should aim at maximizing the O₃ concentration at operating temperatures. This assumption is demonstrated with the set-ups shown in FIGS. 2 and 8, where both traditional immersion with bubble contact (at subambient, ambient and elevated temperatures) and a moist gasphase process (at elevated temperature) are presented. Description of both set-ups is given above. Positive resist wafers (1.2 nm) are exposed for 10 min, at various temperatures (bubble), or at 80° C. (gasphase). Results are shown in FIG. 13. Dissolved O₃ concentration for bubble experiment (bar graph) and cleaning efficiency (line graph and cross) is shown. The cleaning behavior for the bubble experiment is understood from a process limited by kinetic factors in the low temperature range and by ozone solubility in the higher temperature range. The latter limitation is reduced for the moist ozone ambient experiment. By exposing the wafer to a moist atmosphere, a thin condensation layer is formed on the wafer. The O₃ gas ambient maintains a continuous high supply of O₃ (wt % O₃ in gas, ppm in solution). Also, the thin condensation layer reduces the diffusion limitation and allows the shortliving reactive O₃ components to reach the wafer surface, resulting in near 100% removal. Important to note is the fact that the gasphase process, in the absence of moist is unsuccessful.

### ALTERNATE EMBODIMENTS AND EXPLICATION

Ozone Chemistry Consideration

According to another plausible explanation of the result obtained by using the present invention involving ozone in aqueous solution is explained. Ozone decomposition in aqueous solutions is base catalyzed following either a radical (A) or ionic initiation mechanism (B).
(A) O₃+OH⁻-------->*O₂⁻+HO₂ (1)
with*HO₂<===>H+ *O₂ (2)
(B) O₃+OH⁻-------->HO₂⁻+O₂ (3)
with H₂O₂<===>HO₂⁻+O₂ (4)
and O₃+HO₂⁻------->*OH+*O₂+O₂ (5)

Further ozone decomposition occurs along reactions (6) and (7), independent of either type of initiation reaction. It can also be seen that despite the initiation mechanism, either ionic or radical, at least three ozone molecules decompose per unit of hydroxyl ions.
O₃+*O₂⁻-------->*O₃⁻+O₂ (6)
*O₃⁻+H₂O-------->*OH+OH₋+O₂ (7)

In addition to the above described ozone decomposition pathways, also the OH radicals (as formed in reaction (5) and (7)), initiate further ozone decomposition according to reaction pathway (8). Also, a chain type reaction is initiated if the reaction products are combined with reaction (2), (6) and (7).
*OH+O₃--------->*HO₂+O₂ (8)

These decomposition mechanisms are a good model to explain the observed ozone depletion in neutral or caustic aqueous environment. However, in acid environment, the observed decomposition rate of ozone is faster than can be expected from the hydroxyl concentration, given reactions (1-4). Therefore, an additional decomposition mechanism is required. This initiation mechanism is presented in equations (9-11), in combination with the earlier described reactions (2), (6) and (7).
O₃<====>O+O₂ (9)
O+H₂O-------->2*OH (10)

Reactions (1-10) describe the depletion of ozone in aqueous environment. However, in the presence of oxidizable components the situation becomes even more complex, and an overall picture is graphically presented in FIG. 14. Transfer of ozone into aqueous solution is limited by the solubility, thus resulting in ozone loss through purging. The primary reaction is the consumption of ozone by solutes M that become oxidized. Among these reactions is also the oxidation of water to hydrogenperoxide (with resulting equilibrium H₂O₂<==>HO₂⁻+H⁺). This primary reaction is often slow, therefore ozone is likely to decompose via alternative reaction pathways. As such, reaction between initiators I (OH⁻, HO₂⁻, . . . ) and ozone results in the formation of primary radicals (*OH), which may either become scavenged or react further with ozone to yield more free radicals or take part in the advanced oxidation pathway of solutes M. Referring to reactions (1-10) and FIG. 14, it is anticipated that the ozone chemistry can also be controlled chemically, i.e. from selective addition of additives.

The influence of additives on the ozone chemistry as derived from the above, is demonstrated for an overflow bath whereby ozone/water mixtures are prepared in a Gore ozone module (membrane based type mixer) to reduce the presence of O₂/O₃ gas bubbles in the overflow bath. Water flow in the overflow bath (20 l/min), O₂ flow (2 l/min) through the ozone generator and pressure in the ozone module (1 bar) determine the achievable O₃ levels in the bath. These variables are kept constant at the indicated values for the experiments presented here. At all times the ozone level in DI water is allowed to saturate prior to the addition of any chemical. All chemicals used are Ashland GB grade apart acetic acid (99%) which is Baker reagent grade. To eliminate the influence of reaction kinetics, all experiments are performed at room temperature. An Orbisphere labs MOCA electrochemical ozone sensor is used for all ozone measurements.

As represented in FIG. 15, the behavior of acetic acid on the ozone concentration in DI water in an overflow tank is considered by adding 10 ml acetic acid (99 w %) to the DI water after saturation of the ozone level. Almost immediately, the ozone level starts to increase.

Influence of Acetic Acid on the Resist Removal Efficiency of Ozonated Chemistries.

Advanced oxidation processes rely on the presence of OH radicals which are the chain propagating radical in O3 decomposition (K. Sehested, H. Corfitzen, J. Holcman, E. Hart, J. Phys. Chem., 1992, 96, 1005-9, which is hereby incorporated by reference). According to G. Alder and R. Hill in J. Am. Chem. Soc. 1950, 72, (1984), which is hereby incorporated by reference, OH radicals are the main reason for decomposition of organic material. Commonly applied procedures in waste water treatment processes involve e.g. UV radiation, pH or addition of hydrogenperoxide. As such enhancement of OH radical formation is achieved.

Three different experiments using first a hydrogen peroxide, hydrogen peroxide added to acetic acid, and finally acetic acid alone are performed.

The effect of hydrogen peroxide spiking into the ozonated DI water on the removal efficiency of positive resist from silicon wafers can be seen in Table II. It should be noted that the concentration of hydrogen peroxide spiked is in the order of the actual ozone concentration in the DI water. It can be observed that spiking of a 50 μl (Ashland GB, 30%) of H₂O₂ into an 7.5 l tank (0.08 mmol/l) has a strong effect. The measured resist removal rate decreases by a factor of four. Further addition of H₂O₂ reduces the resist removal efficiency even further, until the removal process becomes practically unexisting (2 nm/min removal rate). This is contrary to the effects seen for waste water treatment, where enhanced OH radical availability results in improved removal rates for organic contamination. The organics to be removed in wastewater treatment are dispersed in the solution (as is ozone and OH radicals), while for our purposes, the organic contamination is confined in a layer covering at least part of the substrate. It is likely that for our purposes, not the total amount of ‘ozone and ozone based components’ that is available in the solution, but rather the chemical activity that emerges in the vicinity of the confined layer of organic material near the wafer surface is of importance.

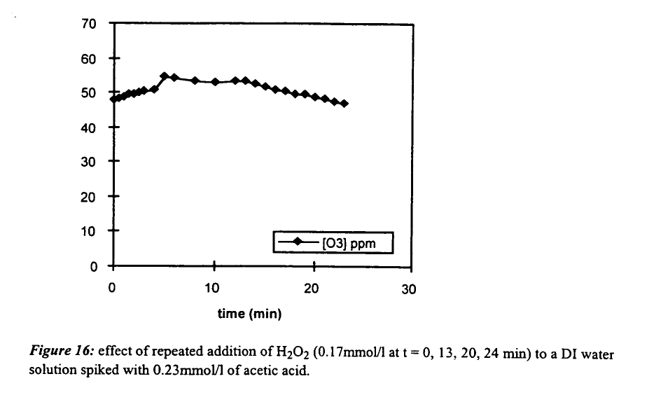

Therefore, in this application, the OH radical catalyzed ozone decomposition mechanism is controlled through scavenging of the OH radicals formed. A scavenger is a substance added to a mixture or other system to counteract the unwanted effects of other constituents. Acetic acid or acetate is a stabilizer of aqueous ozone solutions. In FIG. 16, the combined effect of acetic acid and repeated hydrogenperoxide spiking (OH radical enhancer) on ozone concentration is demonstrated. Despite the spiking of H₂O₂ at time t=0 (0.17 mmol/l), the ozone concentration does increase slightly further in case the DI water is stabilized with only 0.23 mmol/l of acetic acid. Even after several H₂O₂ additions (each time 0.17 mmol/l), the ozone level did not drop below the initial starting level. This confirms the robustness of the acetic acid in quenching the OH radical initiated chain decomposition of ozone.

Table III contains the experimental results for resist removal of a 10-minute process with ozonated DI water when minor amounts of acetic acid are added to the solution. The resist removal is recalculated for the 10 min process time and is expressed as a removal rate (in nm/min). It is worth noting that due to the experimental set-up, the measured ozone concentrations are purely qualitative (separation between ozone sensor and O₂/O₃ gas flow is not always reproducible). Adding between 0.02 mmol/l and 0.24 mmol/l of acetic acid to ozonated DI water, improves the resist removal efficiency by almost 50% compared to the unspiked reference process. The combined effect of acetic acid and hydrogen peroxide spiking is evaluated for resist removal purposes and shown in Table IV. In these runs, the DI water is initially spiked with 0.02 mmol/l of acetic acid, after ozone saturation, a variable concentration of hydrogen peroxide is added, and the effect on resist removal efficiency is evaluated. Adding of hydrogen peroxide in the presence of the acetic acid reduces the resist removal rate, though with far less strong consequences compared to the effect as seen in Table II. Also, it can be seen that the stabilizing effect induced from adding the acetic acid is stronger then observed for acidifying the solution (Table II, with HNO₃).

Higher ozone concentrations are achieved in DI water from the addition of acetic acid. However, the improvement in resist removal efficiency can not solely be explained from the increased ozone concentration upon addition of acetic acid. FIG. 9 plotted impact of acetic acid addition on the resist removal process efficiency number, which is normalized for the ozone concentration. The process efficiency was seen to increase upon acetic acid addition. Therefore some other unknown mechanism is coming into play.

The organic material is confined in a layer at the silicon surface, rather than homogeneously dispersed in the solution as is the case for e.g. waste water treatment. Given the small lifetime of dissolved ozone (t1/2=20 min at room temperature) and reactive ozone species, transfer of waste water ozone knowledge is not feasible for our applications. For good organic removal, sufficient chemical activity (reactive O₃ availability) in the vicinity of the confined layer of organic material near the wafer surface is required. It has been seen that the removal efficiency of organic contamination on silicon wafers is strongly influenced by temperature, ozone concentration and addition of acetic acid. Temperature and ozone concentration requirements are met in the moist ozone gas phase experiment described above. By exposing the wafer to a moist atmosphere, a thin condensation layer is formed on the wafer surface. Due to the ozone gas phase ambient, a continuous supply of ozone compounds through the thin condensation layer, towards the organic contamination at the silicon surface, is maintained. Also in the bubble experiment, ozone containing bubbles continuously contact the confined layer of organic contamination.

However, the critical parameter as far as ozone concentration is concerned, is not solely the total amount of ‘ozone’ that is available in the solution. It rather is the chemical activity that emerges in the vicinity of the confined layer of organic material near the wafer surface. In order for any ozone oxidation process to be successful, one should not necessary maximize the amount of ozone, but improve the transfer efficiency (or availability) of the ozone (molecular and radical) towards the organic contamination to be removed. The latter is likely achieved additionally from acetic acid addition.

Scavenging of OH radicals in oxygenated acetic acid solution leads to the formation of H₂O₂ via reactions described hereunder [K. Sehested et.al, Environ. Sci. Technol. 25, 1589, 1991, which is hereby incorporated by reference].
*OH+CH₃COOH------>*CH₂COOH+H₂O (11)
CH₂COOH+O₂----->*OOCH₂COOH (12)
2*OOCH₂COOH----->0.7H₂O₂+products (13)

The other products formed in reaction (13) are formaldehyde, glyoxylic acid, glycolic acid and organic peroxides.

A reaction of the acetic free radical (reaction (11)), with the resist surface, might make the latter more reactive towards ozone. This could involve abstraction of an hydrogen atom, and formation of an unsaturated bond. This unsaturated bond would then be available for reaction with molecular ozone. Secondly, scavenging of free OH radicals very close to the resist surface. The resulting decomposition of acetic acid according to reactions (11-13) results in the formation of e.g. H₂O₂. Which in its turn could initiate the formation of controlled and localized ‘advanced oxidation power’ (OH radicals) very near to the resist surface.

From the foregoing detailed description, it will be appreciated that numerous changes and modifications can be made to the aspects of the invention without departure from the true spirit and scope of the invention. This true spirit and scope of the invention is defined by the appended claims, to be interpreted in light of the foregoing specification.

TABLE I
Designed experiment settings and results.

| HAC | H₂O₂ | | O₂ | | Pos_er | Neg_er | [O3]av |
|---|---|---|---|---|---|---|---|
| ml | ml | pH | flow | Temp. | nm/min | nm/min | ppm |
| 1 | 0 | 5 | hi | 40 | 51.2 | 7.36 | 18.2 |
| 1 | 0.2 | 2 | lo | 21 | 34.8 | 3.11 | 54.6 |
| 1 | 0.1 | 5 | hi | 40 | 40.1 | 5.97 | 17.2 |
| 1 | 0 | 5 | lo | 21 | 36.9 | 2.60 | 52.6 |
| 0 | 0.2 | 2 | lo | 40 | 19.3 | 0.02 | 14.5 |
| 1 | 0 | 2 | hi | 21 | 36.1 | 2.73 | 44.8 |
| 0 | 0.2 | 5 | lo | 21 | 3.4 | 0.39 | 14.7 |
| 0.5 | 0 | 5 | hi | 40 | 36.3 | 5.91 | 17.1 |
| 0 | 0.2 | 5 | hi | 40 | 4.6 | 1.32 | 5.7 |
| 1 | 0.2 | 5 | lo | 40 | 31.9 | 5.98 | 17.9 |
| 0 | 0 | 2 | lo | 21 | 33.1 | 1.46 | 47.6 |
| 0 | 0.2 | 2 | hi | 21 | 26.8 | 1.96 | 37.9 |
| 0 | 0 | 5 | hi | 21 | 27.0 | 2.58 | 39.8 |
| 0 | 0.1 | 2 | hi | 40 | 20.7 | 2.62 | 11.4 |
| 0 | 0 | 2 | hi | 40 | 31.6 | 3.34 | 15.6 |
| 1 | 0.2 | 5 | hi | 21 | 31.4 | 2.85 | 44.7 |
| 1 | 0.2 | 2 | hi | 40 | 55.9 | 3.78 | 15.9 |
| 1 | 0 | 2 | lo | 40 | 41.8 | 3.96 | 17.7 |
| 0.5 | 0.1 | 5 | hi | 21 | 36.6 | 3.26 | 42.4 |
| 0.5 | 0.2 | 5 | lo | 40 | 37.0 | 2.93 | 15.1 |
| 0.5 | 0.2 | 2 | hi | 40 | 47.3 | 3.22 | 14.4 |
| 0 | 0 | 5 | lo | 40 | 11.9 | 1.24 | 13.6 |
| 1 | 0.1 | 2 | lo | 21 | 34.4 | 1.89 | 49.9 |

TABLE II
Effect of hydrogenperoxide on resist removal
efficiency.

| [O₃] | | | |
|---|---|---|---|
| average | H₂O₂ added | HNO₃ added | Resist removal |
| w-ppm | (ml) | (ml) | (nm/min) |
| 48.0 | 0 | 0 | 38.4 |
| 37.0 | 0.05 | 5.5 | 11.3 |
| 30.9 | 0.05 | 0 | 9.3 |
| 24.7 | 0.1 | 0 | 7.7 |
| 4.5 | 0.5 | 0 | 2.1 |

TABLE III
Effect of acetic acid on resist removal
efficiency

| [O₃] | | HAc | |
|---|---|---|---|
| average | H₂O₂ added | added | Resist removal |
| w-ppm | (ml) | (ml) | (nm/min) |
| 48.0 | 0 | 0 | 38.4 |
| 49.5 | 0 | 0.1 | 47.1 |
| 50.0 | 0 | 1.1 | 51.1 |
| 54.3 | 1 | 1.1 | 34.2 |

TABLE IV
Effect of acetic acid and hydrogen peroxide on
resist removal efficiency.

| [O₃] | | HAc | |
|---|---|---|---|
| average | H₂O₂ added | added | Resist removal |
| w-ppm | (ml) | (ml) | (nm/min) |
| 49.5 | 0 | 0.1 | 47.1 |
| 45.6 | 0.1 | 0.1 | 21.9 |
| 38.6 | 0.2 | 0.1 | 18.1 |
| 46.0 | 1.5 | 0.1 | 22.3 |

1-49. (canceled)

50. A method for removing organic contaminants from a substrate, the organic contaminants resulting from a previous lithographic step, the method comprising the steps of:
contacting at least one side of said substrate with a liquid comprising water, ozone and an additive acting as a scavenger, wherein the proportion of said additive in said liquid is less than 1% molar weight of said liquid; and
maintaining said liquid at a temperature less than the boiling point of said liquid.

51. A method as recited in claim 50, wherein said temperature is lower than 100° C.

52. A method as recited in claim 50, wherein said liquid is sprayed over at least one side of said substrate.

53. A method as recited in claim 50, wherein said temperature is between 16° C. and 99° C.

54. A method according as recited in claim 53, wherein the temperature of said liquid is between 20° C. and 90° C.

55. A method according as recited in claim 54, wherein the temperature of said liquid is between 60° C. and 80° C.

56. A method as recited in claim 50, wherein said liquid is subjected to megasone agitation.

57. A method as recited in claim 50, wherein the ozone is bubbled through the liquid.

58. A method as recited in claim 50, wherein the organic contamination is a confined layer covering at least part of said substrate.

59. A method as recited in claim 58, wherein said confined layer has a thickness in a range of submonolayer coverage and 1 μm.

60. A method as recited in claim 50, wherein said additive is acting as OH radical scavenger.

61. A method as recited in claim 50, said additive is selected from the group consisting of a carboxylic acid, a phosphonic acid, and salts thereof.

62. A method as recited in claim 61, wherein said additive is acetic acid.

63. A method according to claim 50, wherein the proportion of said additive in said liquid is less than 0.1% molar weight of said liquid.

64. A method according to claim 63, wherein the proportion of said additive in said liquid is less than 0.1% molar weight of said liquid.

65. A method as recited in claim 50, wherein the ozone includes ozone bubbles and wherein the ozone bubbles are contacting said organic contaminants.

66. A method as recited in claim 50, further comprising the step of rinsing said substrate with a solution.

67. A method as recited in claim 66, wherein said solution comprises de-ionised water.

68. A method as recited in claim 67, wherein said solution further comprises at least one solution selected from the group consisting of HCl, HF, HNO₃, CO₂ and O₃.

69. A method as recited in claim 66, wherein said solution is subjected to megasone agitation.

70. A method as recited in claim 50, wherein said substrate is a silicon wafer.
